(19) United States
(12) Patent Application Publication
(10) Pub. No.: US 2022/0382343 A1
(43) Pub. Date: Dec. 1, 2022

(54) EXPANSION CARD FIXING STRUCTURE

(71) Applicant: TAI-SHENG HAN, New Taipei (TW)

(72) Inventor: TAI-SHENG HAN, New Taipei (TW)

(73) Assignee: EVGA CORPORATION, New Taipei (TW)

(21) Appl. No.: 17/397,904

(22) Filed: Aug. 9, 2021

(30) Foreign Application Priority Data
May 25, 2021 (TW) 110206015

(51) Int. Cl. G06F 1/18; H05K 7/20

(52) U.S. Cl. CPC G06F 1/185; H05K 7/2039

(57) ABSTRACT

An expansion card fixing structure comprises a motherboard with at least one first fixing seat and at least one expansion card disposed thereon, inside the first fixing seat is formed with a first screw hole assembling with an expansion assembling hole on an end edge of the expansion card; at least one extension fixing member formed with a first screw connection part assembling with the first screw hole, a top of the extension fixing member is formed with a second screw connection part; and a heat sink formed with at least one assembling groove and at least one through hole communicating with each other for the second screw connection part to pass through, the heat sink is provided with a second fixing seat in the assembling groove, and inside the second fixing seat is formed with a second screw hole assembling with the second screw connection part.

### BACKGROUND OF THE INVENTION

### Field of Invention

The invention is related to an expansion card fixing structure, and more particularly to an expansion card fixing structure capable of aligning and locking quickly to avoid poor assembly and prevent components from interfering with each other to cause board bending or damage.

### Related Art

With the continuous development of technology, the functions of electronic products are constantly improving, and the use of computers is relatively important. Motherboard is a very important operating core of computer devices, with the improvement of motherboard functions, the M.2 interface is a fast storage slot that is widely used on motherboards, and the waste heat generated by the storage devices on the M.2 slot due to high performance is mainly conducted and dissipated by the thermal module. Since the M.2 interface slots are all designed with an obliquely plug-in elastic plate, the storage device will be tilted at a specific angle due to the elastic plate before the storage device is fixed. Therefore, the conventional motherboard is provided with locking holes that can fix the storage device, in addition, it is necessary to have locking holes for fixing the thermal module, but this causes the motherboard to be required to use different holes to respectively align and assemble the storage device and the thermal module. When the storage device is mounted, it is required to disassemble and assemble the thermal module first, which will cause inconvenience in assembly and easily lead to poor assembly. Or the conventional motherboard uses a single hole for fixing the thermal module and the storage device, but the thermal module is usually assembled by a straight up and down locking method, so users usually cannot easily and accurately align the thermal module and the storage device with the locking hole of the motherboard at the same time, which may easily cause offset of the storage device during the assembly process, resulting in the storage device to collide with other electronic components to cause damage. Moreover, the assembled storage device will be attached to the thermal pad at the bottom of the thermal module, so during the process of dismounting the thermal module in a straight up and down manner, the storage device will interfere with other components due to the resilience force generated by the oblique plug-in design and will cause damage or board bending.

Therefore, the inventor of the invention and relevant manufacturers engaged in this industry are eager to research and make improvement to solve the above-mentioned problems and drawbacks in the prior art.

### SUMMARY OF THE INVENTION

Therefore, in order to effectively solve the above-mentioned problems, a main object of the invention is to provide an expansion card fixing structure capable of aligning and locking quickly to avoid poor assembly and prevent components from interfering with each other to cause board bending or damage.

In order to achieve the above-mentioned object, the invention provides an expansion card fixing structure at least comprising a motherboard with at least one first fixing seat and at least one expansion card disposed thereon, inside the first fixing seat is formed with a first screw hole, a top of the first fixing seat is formed with a supporting surface and a top protruding part, an end edge of the expansion card is formed with an expansion assembling hole and a bottom surface of the end edge is attached to the supporting surface, and the top protruding part passes through the expansion assembling hole; at least one extension fixing member, a bottom of the extension fixing member is formed with a first screw connection part assembling with the first screw hole, a top of the extension fixing member is formed with a second screw connection part, and the extension fixing member is formed with an extension lock hole at an end edge of the second screw connection part; and a heat sink formed with at least one assembling groove and at least one through hole communicating with each other for the second screw connection part to pass through, the heat sink is provided with a second fixing seat in the assembling groove, and inside the second fixing seat is formed with a second screw hole assembling with the second screw connection part.

According to one embodiment of the invention, wherein the first screw connection part penetrates the top protruding part and the supporting surface.

According to one embodiment of the invention, wherein at least one board through hole is formed on the motherboard, and a bottom protruding part is formed on a bottom of the first fixing seat to be assembled with the board through hole.

According to one embodiment of the invention, wherein a number of screw threads of the first screw connection part is greater than a number of screw threads of the second screw connection part.

According to one embodiment of the invention, wherein a width of the second screw connection part is greater than a width of the first screw connection part.

According to one embodiment of the invention, wherein a top surface of the end edge of the expansion card is attached to a bottom protruding surface of the extension fixing member, so that the end edge of the expansion card is limited between the extension fixing member and the supporting surface.

According to one embodiment of the invention, wherein a fixing lock hole is formed on a top of the second fixing seat.

According to one embodiment of the invention, wherein a bottom of the heat sink is provided with a thermal pad, a top surface of the thermal pad is attached to a bottom surface of the heat sink, and a bottom surface of another side of the thermal pad is attached to a top surface of the expansion card.

According to one embodiment of the invention, wherein a top protruding surface is formed on the extension fixing member, a recessed surface is formed on the bottom of the heat sink, and the recessed surface is supported and placed on the top protruding surface.

### BRIEF DESCRIPTION OF THE DRAWINGS

FIG. 1 is a perspective assembly view of an expansion card fixing structure of the invention;

FIG. 2 is a partial cross-sectional view of the expansion card fixing structure of the invention;

FIG. 3 is a first assembly diagram of the expansion card fixing structure of the invention;

FIG. 4 is a second assembly diagram of the expansion card fixing structure of the invention;

FIG. 5 is a first assembly cross-sectional view of the expansion card fixing structure of the invention;

FIG. 6 is a third assembly diagram of the expansion card fixing structure of the invention;

FIG. 7 is a fourth assembly diagram of the expansion card fixing structure of the invention; and

FIG. 8 is a second assembly cross-sectional view of the expansion card fixing structure of the invention.

### DETAILED DESCRIPTION OF THE INVENTION

The above-mentioned object of the invention and its structural and functional features will be described based on the preferred embodiments with reference to the attached drawings.

In the following, for the formation and technical content related to an expansion card fixing structure in the invention, various applicable examples are exemplified and explained in detail with reference to the attached drawings; however, the invention is of course not limited to the enumerated embodiments, drawings, or detailed descriptions.

Furthermore, those who are familiar with this technology should also understand that the enumerated embodiments and attached drawings are only for reference and explanation, and are not used to limit the invention; other modifications or alterations that can be easily implemented based on the detailed descriptions of the invention are also deemed to be within the scope without departing from the spirit or intention thereof as defined by the appended claims and their legal equivalents.

Furthermore, the directional terms mentioned in the following embodiments, for example: “above”, “below”, “left”, “right”, “front”, “rear”, etc., are only referring to the directions of the attached drawings. Therefore, the directional terms are used to illustrate rather than limit the invention. In addition, in the following embodiments, the same or similar elements will be labeled with the same or similar numerals.

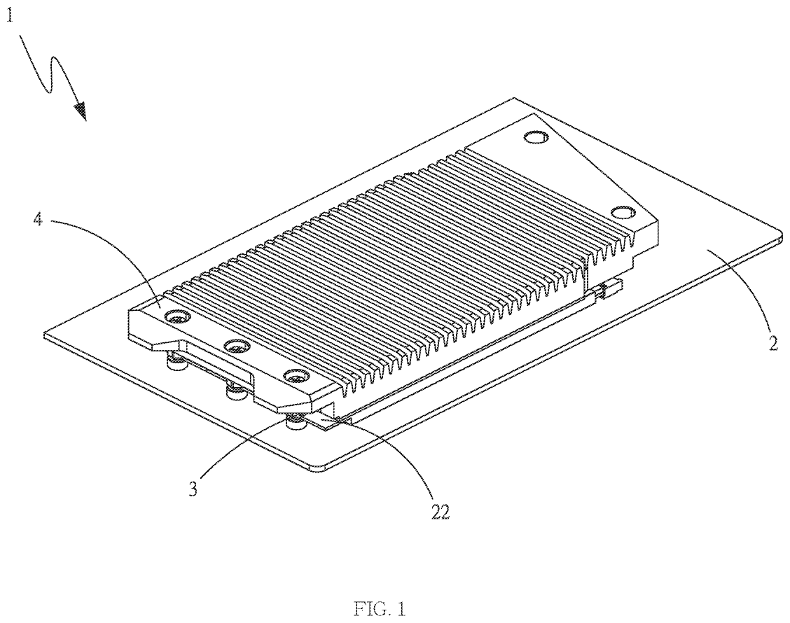

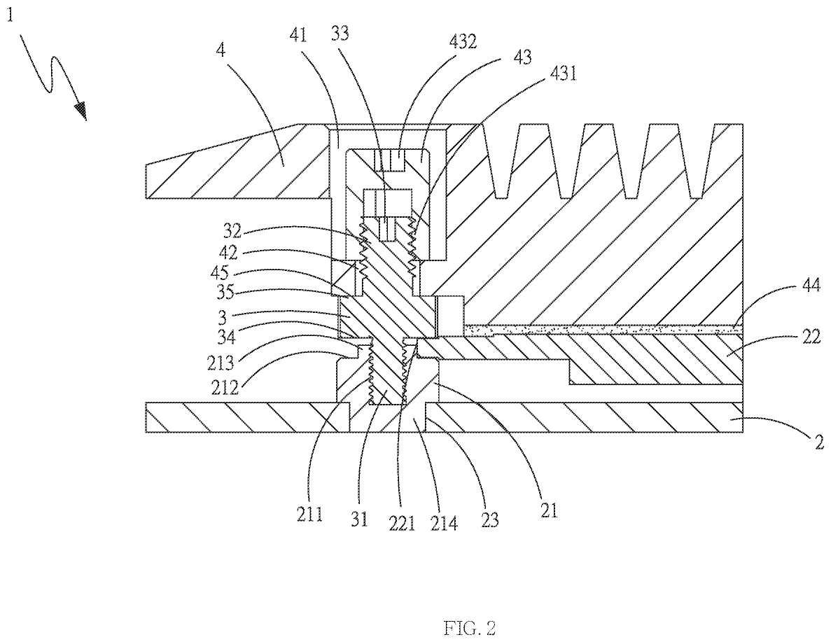

Please refer to FIGS. 1 and 2 for a perspective assembly view and a partial cross-sectional view of an expansion card fixing structure 1 of the invention respectively. It can be clearly seen from the figures that the expansion card fixing structure 1 comprises a motherboard 2, at least one extension fixing member 3 and a heat sink 4.

Wherein the motherboard 2 is provided with at least one first fixing seat 21, and at least one expansion card 22, and formed with at least one board through hole 23. In this embodiment, the motherboard 2 is provided with the three first fixing seats 21 and the three expansion cards 22 and the three board through holes 23, wherein inside each of the first fixing seats 21 is formed with a first screw hole 211, the first screw hole 211 is an internal screw thread, a supporting surface 212 is formed on the first fixing seat 21, and the first fixing seat 21 is formed with a top protruding part 213 on the supporting surface 212. In addition, a bottom protruding part 214 is formed on a bottom of the first fixing seat 21, and the bottom protruding part 214 is assembled with the board through hole 23. The first screw hole 211 penetrates the top protruding part 213 and the supporting surface 212, and the top protruding part 213 passes through an expansion assembling hole 221.

Wherein a first screw connection part 31 is formed at a bottom of each of the extension fixing members 3, the first screw connection part 31 is an external screw thread, and the first screw connection part 31 is screwed with the supporting surface 212 and the first screw hole 211 through the top protruding part 213. A top of the extension fixing member 3 is formed with a second screw connection part 32, and the extension fixing member 3 is formed with an extension lock hole 33 at an end edge of the second screw connection part 32. In addition, a number of screw threads of the first screw connection part 31 is greater than a number of screw threads of the second screw connection part 32, and a width of the second screw connection part 32 is greater than a width of the first screw connection part 31. The bottom of the extension fixing member 3 is formed with a bottom protruding surface 34, a top of the extension fixing member 3 is formed with a top protruding surface 35, and a top surface of an end edge of the expansion card 22 is attached to the bottom protruding surface 34 of the extension fixing member 3, so that the end edge of the expansion card 22 is limited between the extension fixing member 3 and the supporting surface 212.

Wherein a side of the heat sink 4 is formed with at least one assembling groove 41 and at least one through hole 42 that communicate with each other. In this embodiment, the side of the heat sink 4 is formed with the three assembling grooves 41 and the three through holes 42, the heat sink 4 is provided with a second fixing seat 43 in each of the assembling grooves 41, a thermal pad 44 is provided at a bottom of the heat sink 4, a top surface of the thermal pad 44 is attached to a bottom surface of the heat sink 4, and a bottom surface of another side of the thermal pad 44 is attached to a top surface of the expansion card 22. And the bottom of the heat sink 4 is formed with a recessed surface 45, the recessed surface 45 is supported and placed on the top protruding surface 35, inside the second fixing seat 43 is formed with a second screw hole 431 assembling with the second screw connection part 32, and a fixing lock hole 432 is formed on a top of the second fixing seat 43.

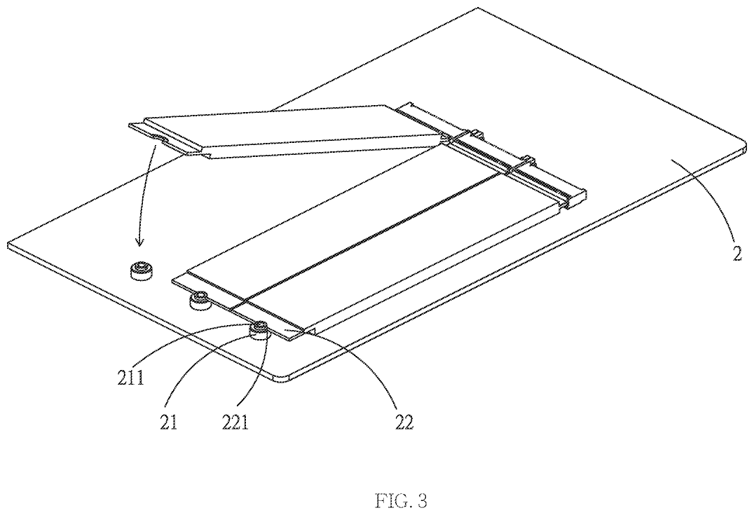

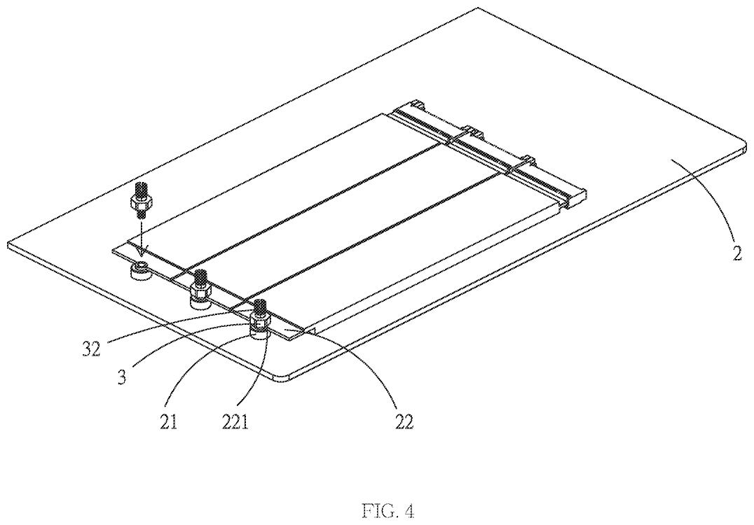

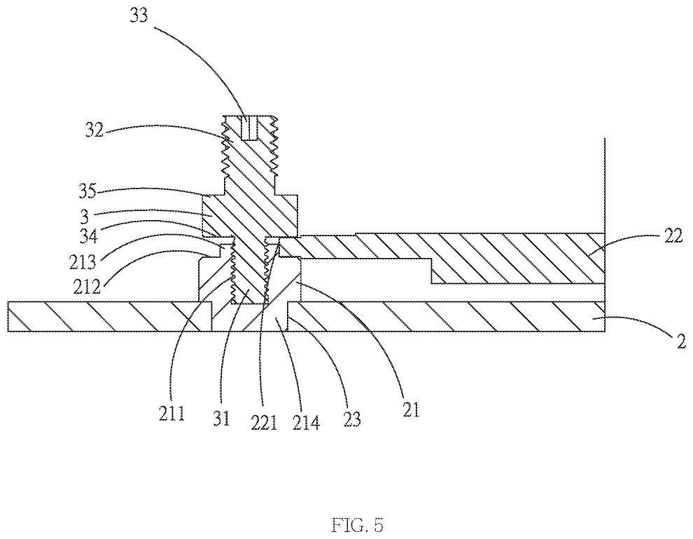

Please refer to the aforementioned drawings and FIGS. 3, 4 and 5 for a first assembly diagram, a second assembly diagram and a first assembly cross-sectional view of the expansion card fixing structure 1 of the invention respectively. Wherein the motherboard 2 is disposed with the first fixing seat 21 in each of the board through holes 23 respectively, after one end of each of the expansion cards 22 is assembled in an oblique plug-in structure of the motherboard 2, another end of each of the expansion cards 22 is assembled with the top protruding part 213 through the expansion assembling hole 221, so that the top protruding part 213 passes through the expansion assembling hole 221, and the expansion card 22 and the motherboard 2 are disposed horizontally. Then the first screw connection part 31 of each of the extension fixing members 3 is screwed and locked with each of the first screw holes 211, and the screw-locking method can be achieved with a screw-locking tool in cooperation with the extension lock hole 33. Thereby, a front end of the expansion card 22 is restricted by the top protruding part 213, and the top surface of the end edge of the expansion card 22 is attached to the bottom protruding surface 34 of the extension fixing member 3, and a bottom surface of the end edge of the expansion card 22 is attached to the supporting surface 212, so that the end edge of the expansion card 22 is limited between the extension fixing member 3 and the supporting surface 212.

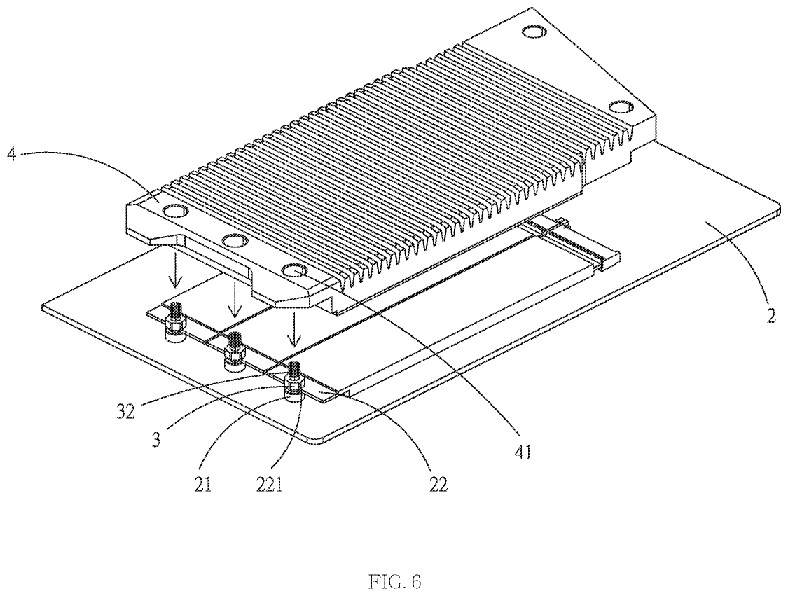

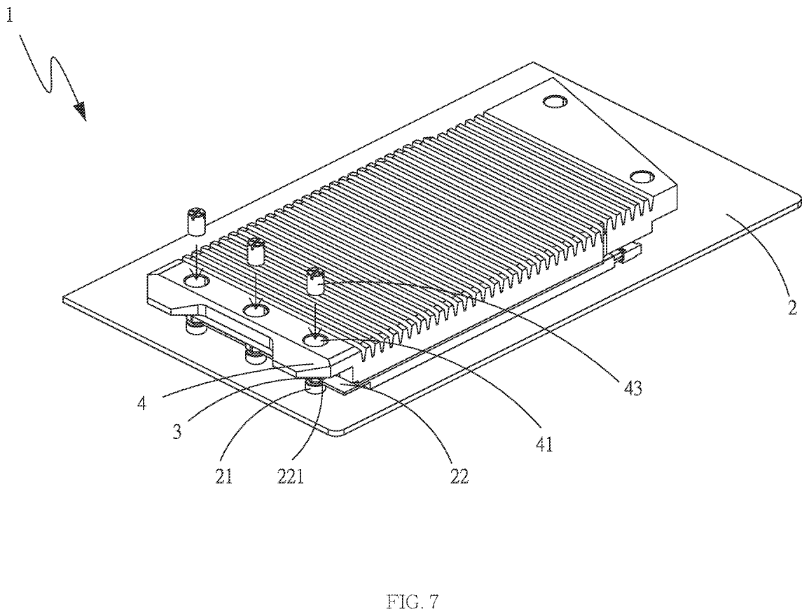

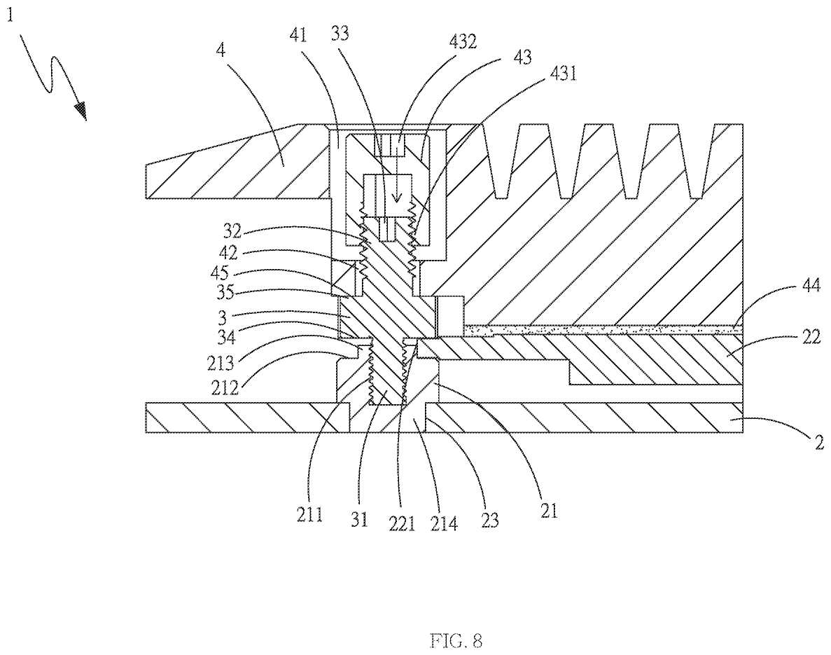

Please refer to the aforementioned drawings and FIGS. 6, 7 and 8 for a third assembly diagram, a fourth assembly diagram and a second assembly cross-sectional view of the expansion card fixing structure 1 of the invention respectively. Wherein after the expansion card 22 is limited on the motherboard 2, the heat sink 4 can be assembled on the motherboard 2 and attached to the expansion card 22, the thermal pad 44 is disposed between the heat sink 4 and the expansion card 22, the second screw connection part 32 is inserted into the through hole 42 of the heat sink 4, and the recessed surface 45 is attached to the top protruding surface 35. Then the second fixing seat 43 can be disposed in the assembling groove 41 and threadly locked with the second screw connection part 32, and with a screw-locking tool cooperating with the fixing lock hole 432, the second fixing seat 43 is screwed and locked on the second screw connection part 32. Since a number of screw threads of the first screw connection part 31 is greater than a number of screw threads of the second screw connection part 32, when the second fixing seat 43 is threadly locked, the first screw connection part 31 will not rotate in the first screw hole 211, and when the second fixing seat 43 is screwed and locked with the second screw connection part 32, the second fixing seat 43 is simultaneously fixed in the assembling groove 41, and the heat sink 4 is limited on the extension fixing member 3. Conversely, when the heat sink 4 is to be disassembled, the second fixing seat 43 can be disassembled from the second screw connection part 32, the heat sink 4 can be detached from the second screw connection part 32, and the expansion card 22 is still fixed and limited on the motherboard 2 by the extension fixing member 3 and the first fixing seat 21. Thereby the expansion card 22 and the heat sink 4 can be locked on the motherboard 2 through the single board through hole 23, the expansion card 22 and the heat sink 4 are respectively limited by the extension fixing member 3 and the second fixing seat 43. After the heat sink 4 is removed, the expansion card 22 will not tilt due to attachment of the thermal pad 44 or a resilience force generated by diagonal plug-in, thereby achieving quick alignment and locking to achieve efficacies of avoiding poor assembly and preventing the components from interfering with each other to cause board bending or damage.

It is to be understood that the above description is only the preferred embodiments of the present invention and is not used to limit the present invention, and changes in accordance with the concepts of the present invention may be made without departing from the spirit of the present invention, for example, the equivalent effects produced by various transformations, variations, modifications and applications made to the configurations or arrangements shall still fall within the scope covered by the appended claims of the present invention.

What is claimed is:

1. An expansion card fixing structure comprising:
a motherboard with at least one first fixing seat and at least one expansion card disposed thereon, inside the first fixing seat being formed with a first screw hole, a top of the first fixing seat being formed with a supporting surface and a top protruding part, an end edge of the expansion card being formed with an expansion assembling hole and a bottom surface of the end edge being attached to the supporting surface, and the top protruding part passing through the expansion assembling hole;
at least one extension fixing member, a bottom of the extension fixing member being formed with a first screw connection part assembling with the first screw hole, a top of the extension fixing member being formed with a second screw connection part, and the extension fixing member being formed with an extension lock hole at an end edge of the second screw connection part; and
a heat sink formed with at least one assembling groove and at least one through hole communicating with each other for the second screw connection part to pass through, the heat sink being provided with a second fixing seat in the assembling groove, and inside the second fixing seat being formed with a second screw hole assembling with the second screw connection part.

2. The expansion card fixing structure as claimed in claim 1, wherein the first screw connection part penetrates the top protruding part and the supporting surface.

3. The expansion card fixing structure as claimed in claim 1, wherein at least one board through hole is formed on the motherboard, and a bottom protruding part is formed on a bottom of the first fixing seat to be assembled with the board through hole.

4. The expansion card fixing structure as claimed in claim 1, wherein a number of screw threads of the first screw connection part is greater than a number of screw threads of the second screw connection part.

5. The expansion card fixing structure as claimed in claim 1, wherein a width of the second screw connection part is greater than a width of the first screw connection part.

6. The expansion card fixing structure as claimed in claim 1, wherein a top surface of the end edge of the expansion card is attached to a bottom protruding surface of the extension fixing member, so that the end edge of the expansion card is limited between the extension fixing member and the supporting surface.

7. The expansion card fixing structure as claimed in claim 1, wherein a fixing lock hole is formed on a top of the second fixing seat.

8. The expansion card fixing structure as claimed in claim 1, wherein a bottom of the heat sink is provided with a thermal pad, a top surface of the thermal pad is attached to a bottom surface of the heat sink, and a bottom surface of another side of the thermal pad is attached to a top surface of the expansion card.

9. The expansion card fixing structure as claimed in claim 1, wherein a top protruding surface is formed on the extension fixing member, a recessed surface is formed on the bottom of the heat sink, and the recessed surface is supported and placed on the top protruding surface.
